(19) United States
(12) Patent Application Publication
(10) Pub. No.: US 2010/0271879 A1
(43) Pub. Date: Oct. 28, 2010

(54) SEMICONDUCTOR INTEGRATED CIRCUIT DEVICE

(76) Inventor: Eiichi Makino, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/754,206

(22) Filed: Apr. 5, 2010

(30) Foreign Application Priority Data
Apr. 24, 2009 (JP) 2009-106671

(51) Int. Cl. G11C 16/04; G11C 5/14; G11C 8/00

(52) U.S. Cl. 365/185.17; 365/226; 365/230.03

(57) ABSTRACT

A semiconductor integrated circuit includes a memory cell array including a plurality of planes each including a plurality of memory cells, a power supply voltage generating circuit including a common voltage generating circuit which maintains a fixed voltage supply capability, and a plurality of voltage generating circuits which are disposed in accordance with a number of the plurality of planes, and a control circuit configured to control the power supply voltage generating circuit.

### CROSS-REFERENCE TO RELATED APPLICATIONS

This application is based upon and claims the benefit of priority from prior Japanese Patent Application No. 2009-106671, filed Apr. 24, 2009, the entire contents of which are incorporated herein by reference.

### BACKGROUND OF THE INVENTION

1. Field of the Invention

The present invention relates to a semiconductor integrated circuit device, which is applicable to, for example, a NAND flash memory.

2. Description of the Related Art

In recent years, by virtue of such advantages as large capacity and nonvolatility, NAND flash memories, for example, have been mounted in various electronic apparatuses including portable audio devices.

Under the circumstances, main challenging problems of the NAND flash memory, which are to be addressed hereafter, are an improvement of its functions and a further increase in memory capacity. In order to realize the increase in capacity, it is thought to be a prospective solution to construct a memory cell array in a multi-plane configuration, thereby to suppress degradation in characteristics due to an increase in word line length and bit line length, while promoting microfabrication of memory cells (Jpn. Pat. Appln. KOKAI Publication No. H6-190587).

### BRIEF SUMMARY OF THE INVENTION

According to an aspect of the present invention, there is provided a semiconductor integrated circuit comprising: a memory cell array including a plurality of planes each including a plurality of memory cells; a power supply voltage generating circuit including a common voltage generating circuit which maintains a fixed voltage supply capability, and a plurality of voltage generating circuits which are disposed in accordance with a number of the plurality of planes; and a control circuit configured to control the power supply voltage generating circuit.

### BRIEF DESCRIPTION OF THE SEVERAL VIEWS OF THE DRAWING

FIG. 1 is a block diagram showing an entire structure example of a semiconductor integrated circuit device according to a first embodiment of the present invention;

FIG. 2 is an equivalent circuit diagram showing a structure example of a block in FIG. 1;

FIG. 3 is a block diagram showing a memory cell array and a power supply voltage generating circuit according to the first embodiment;

FIG. 4 is a block diagram showing a wiring structure example of the semiconductor integrated circuit device according to the first embodiment;

FIG. 5 shows a wiring load capacitance according to the first embodiment;

FIG. 6 shows the relationship between the number of selected planes and a wiring load capacitance in the first embodiment;

FIG. 7 is a graph showing rising characteristics of the semiconductor integrated circuit device according to the first embodiment;

FIG. 8 is a graph showing rising characteristics of a semiconductor integrated circuit device according to a comparative example;

FIG. 9 is a block diagram showing a memory cell array and a power supply voltage generating circuit according to a second embodiment of the invention;

FIG. 10 is a block diagram showing a memory cell array and a power supply voltage generating circuit according to a third embodiment of the invention; and

FIG. 11 is a block diagram showing a memory cell array and a power supply voltage generating circuit according to a comparative example.

### DETAILED DESCRIPTION OF THE INVENTION

If a multi-plane implementation of two planes or more is promoted, a load capacitance varies in accordance with the variation of the number of selected planes, and consequently the charge time greatly varies depending on the number of selected planes. Thus, there is a tendency that the operation margin deteriorates.

Embodiments of the present invention will now be described with reference to the accompanying drawings. In the description below, common parts are denoted by like reference numerals throughout the drawings. Although a NAND flash memory is described below as an example of a semiconductor integrated circuit device of the invention, the invention is not limited to the NAND flash memory.

### First Embodiment

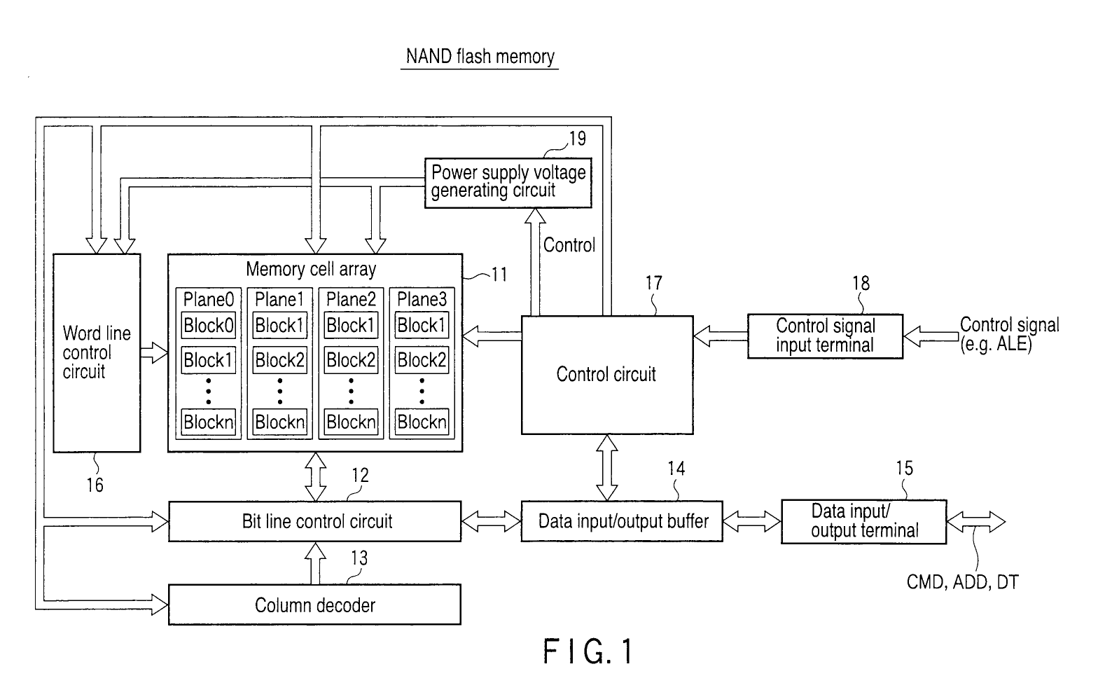

Referring to FIG. 1 to FIG. 8, a semiconductor integrated circuit device according to a first embodiment of the invention is described.

### <1. Structure Example>

### 1-1. Entire Structure Example

To begin with, referring to FIG. 1, an entire structure example of the semiconductor integrated circuit device according to the first embodiment of the invention is described.

As shown in FIG. 1, the semiconductor integrated circuit device according to the first embodiment comprises a memory cell array 11, a bit line control circuit 12, a column decoder 13, a data input/output buffer 14, a data input/output terminal 15, a word line control circuit 16, a control circuit 17, a control signal input terminal 18 and a power supply voltage generating circuit 19.

The memory cell array 11 includes a plurality of planes. In the case of the present embodiment, the memory cell array 11 has a multi-plane configuration comprising four planes (Plane 0, Plane 1, Plane 2 and Plane 3). Each of the planes comprises a plurality of blocks (Block 0 to Block n). The word line control circuit 16 which controls word lines, the bit line control circuit 12 which controls bit lines, the control circuit 17 and the power supply voltage generating circuit 19 are electrically connected to the memory cell array 11.

The bit line control circuit 12 reads out data of memory cells in the memory cell array 11 via the bit lines, and detects the states of memory cells in the memory cell array 11 via the bit lines. In addition, the bit line control circuit 12 applies a write control voltage to the memory cells in the memory cell array 11 via the bit lines, thereby executing data write in the memory cells. The column decoder 13, data input/output buffer 14 and control circuit 17 are electrically connected to the bit line control circuit 12.

A data memory circuit (not shown) is provided in the bit line control circuit 12, and the data memory circuit is selected by the column decoder 13. The data of the memory cell, which is read out to the data memory circuit, is output to the outside from the data input/output terminal via the data input/output buffer 14. The data input/output terminal 15 is connected to, for example, a host apparatus which is provided outside the NAND flash memory.

The host apparatus is, for example, a microcomputer, and receives data which is output from the data input/output terminal 15. Further, the host apparatus outputs various commands CMD, addresses ADD and data DT, which control the operation of the NAND flash memory. The write data DT, which is input from the host apparatus to the data input/output terminal 15, is supplied via the data input/output buffer 14 to the data memory circuit (not shown) which is selected by the column decoder 13. On the other hand, the command CMD and the address ADD are supplied to the control circuit 17.

The word line control circuit 16 selects a word line in the memory cell array 11, and applies to the selected word line a voltage necessary for read, write or erase, which is supplied from the power supply voltage generating circuit 19.

The control circuit 17 is electrically connected to the memory cell array 11, bit line control circuit 12, column decoder 13, data input/output buffer 14, word line control circuit 16 and power supply voltage generating circuit 19. These connected structural circuits are controlled by the control circuit 17. The control circuit 17 is connected to the control signal input terminal 18, and is controlled by a control signal, such as an ALE (address latch enable) signal, which is input from the external host apparatus via the control signal input terminal 18. In addition, the control circuit 17 outputs a control signal (to be described later) to the power supply voltage generating circuit 19, and controls the power supply voltage generating circuit 19.

The power supply voltage generating circuit 19 supplies necessary voltages to the memory cell array 11 and word line control circuit 16, in accordance with the control by the control circuit 17.

The word line control circuit 16, bit line control circuit 12, column decoder 13, control circuit 17 and power supply voltage generating circuit 19 constitute a write circuit, a read circuit and an erase circuit.

### 1-2. Structure Example of Block

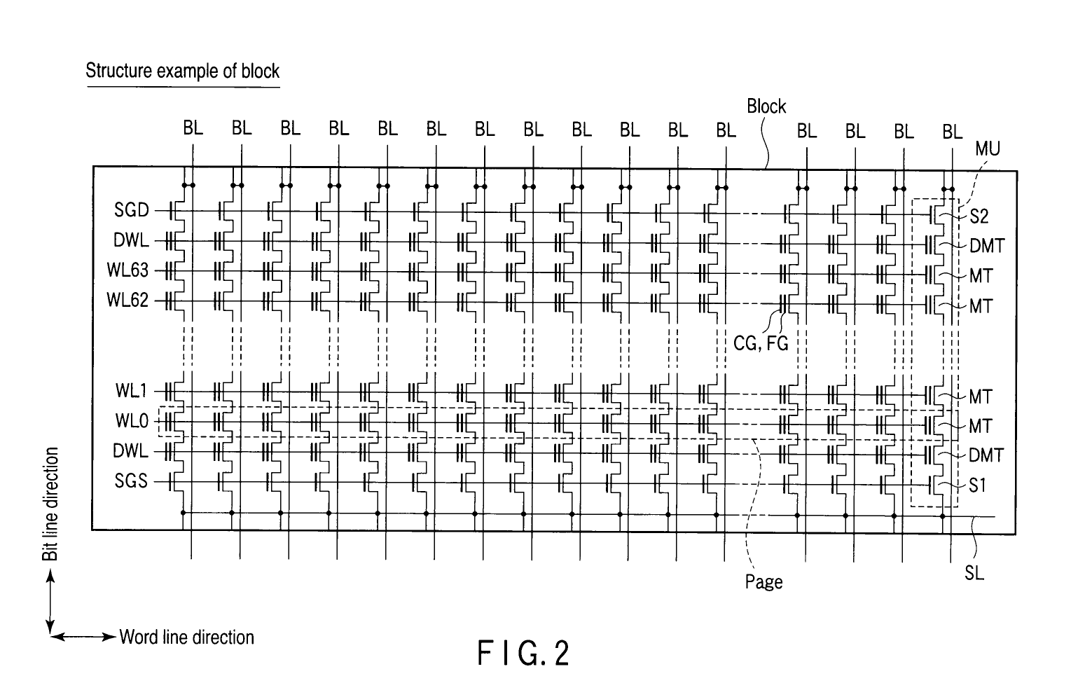

Next, referring to FIG. 2, a structure example of the block is described. One block in FIG. 1 is described by way of example. In the case of this example, the memory cell transistors in the block are erased batchwise. In short, the block is a data erase unit.

The block comprises a plurality of memory cell units MU which are arranged in a WL (word line) direction. The memory cell unit MU comprises a NAND string, a select transistor S1 connected to one end of the NAND string, and a select transistor S2 connected to the other end of the NAND string. The NAND string comprises 64 memory cell transistors having current paths connected in series, and two dummy cell transistors DMT. In this example, memory cell transistors neighboring the source line SL and bit line BL are the dummy cell transistors DMT. Since these cell transistors are not made to function as memory cells, the defect ratio of the memory cell unit MU can effectively be reduced.

Each of the memory cell transistors MT and dummy cell transistors DMT has a multilayer structure comprising a gate insulation film, a charge accumulation layer FG, an inter-gate insulation film and a control electrode layer CG, which are successively provided on a semiconductor substrate.

In the present embodiment, the NAND string comprises 64 memory cell transistors MT. However, the number of memory cell transistors MT is not limited to 64, and may be two or more, for example, 8 or 16.

One end of the current path of the select transistor S1 is connected to the source line SL, and one end of the current path of the select transistor S2 is connected to the bit line BL.

The word line WL extends in the WL direction, and is connected commonly to the control electrodes of the plural memory cell transistors MT in the WL direction. A select gate line SGS extends in the WL direction, and is connected commonly to the plural select transistors S1 in the WL direction. Similarly, a select gate line SGD extends in the WL direction, and is connected commonly to the plural select transistors S2 in the WL direction.

### 1-3. Structure Example of the Memory Cell Array and the Power Supply Voltage Generating Circuit

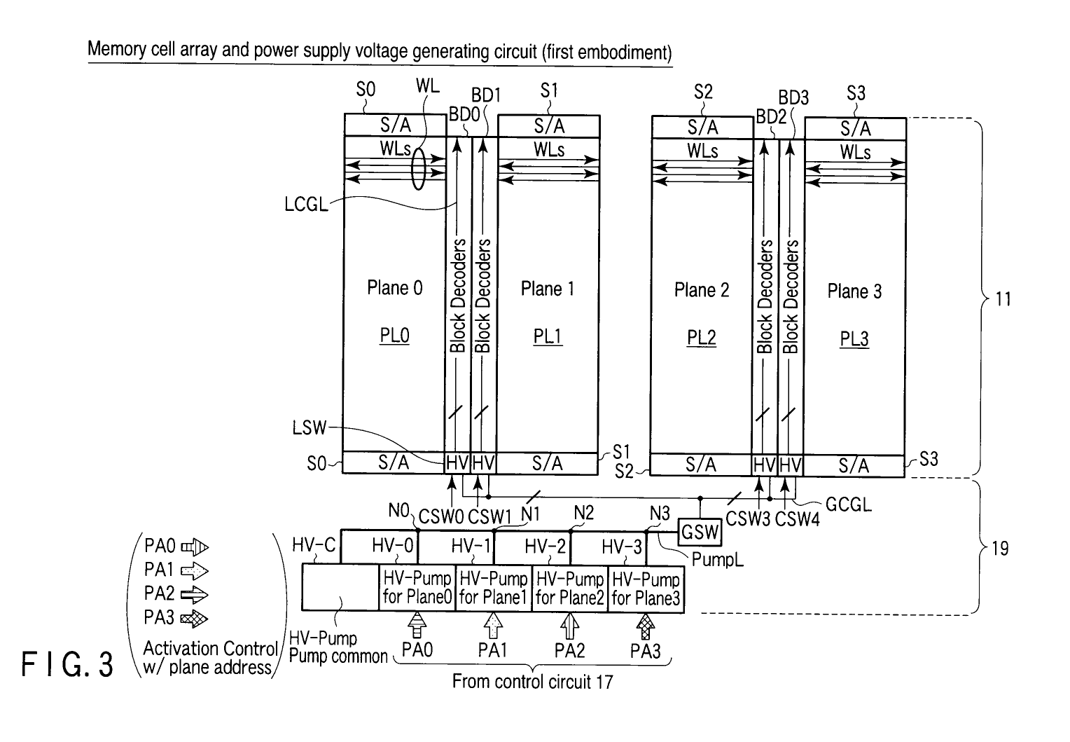

Next, referring to FIG. 3, a description is given of a structure example of the memory cell array 11 and the power supply voltage generating circuit 19. As shown in FIG. 3, in this example, the memory cell array 11 comprises four planes (Plane 0, Plane 1, Plane 2, Plane 3).

The plane PL0 comprises a plurality of blocks (depiction is omitted), sense amplifiers S0, a block decoder BD0 and a local switch LSW (HV).

Although a detailed description of the block is omitted, at least a plurality of word lines WLs are arranged along the word line direction, as shown in FIG. 3. The sense amplifiers S0 are disposed in a manner to sandwich the plural blocks in the bit line direction, and read out data from the memory cell transistors. The block decoder BD0 includes a local control line LGCL along the bit line direction and selects one of the plural blocks in accordance with a block select signal. The local switch LSW switches ON/OFF of the block decoder BD0 in accordance with a local control signal CSWO which is input from the control circuit 17.

The other planes PL1 to PL3 have substantially the same structure as the plane PL0, and a detailed description thereof is omitted.

The power supply voltage generating circuit 19 comprises a global switch circuit GSW, a common voltage generating circuit HV-C, and a plurality of voltage generating circuits HV-0 to HV-3.

The global switch circuit GSW switches and supplies the power supply voltage, which is supplied from the common voltage generating circuit HV-C and voltage generating circuits HV-0 to HV-3, to the selected plane (PL0 to PL3). The global switch circuit GSW and the plural planes PL0 to PL3 are electrically connected by a global control gate line GCGL.

The common voltage generating circuit (HV-Pump) HV-C maintains a fixed voltage supply capability regardless of the number of planes (PL0 to PL3), and generates a common power supply voltage. In addition, the common voltage generating circuit HV-C is set in an inactive state when the NAND flash memory chip is in a standby state.

The voltage generating circuits (HV-Pump for Plane 0 to HV-Pump for Plane 3) HV-0 to HV-3 are disposed in association with the number (four in this example) of the planes (PL0 to PL3), and are selected and activated by control signals (Activation Control w/ plane address) PA0 to PA3 which are input from the control circuit 17. The selected voltage generating circuit (HV-0 to HV-3) generates an optimal power supply voltage for each plane for charging a wiring load capacitance of each selected plane (PL0 to PL3). The details will be described later.

The common voltage generating circuit HV-C and voltage generating circuits HV-0 to HV-3 and the global switch circuit GSW are electrically connected by a pump section wiring PumpL via nodes N0 to N3.

### 1-4. Structure Example of Wiring

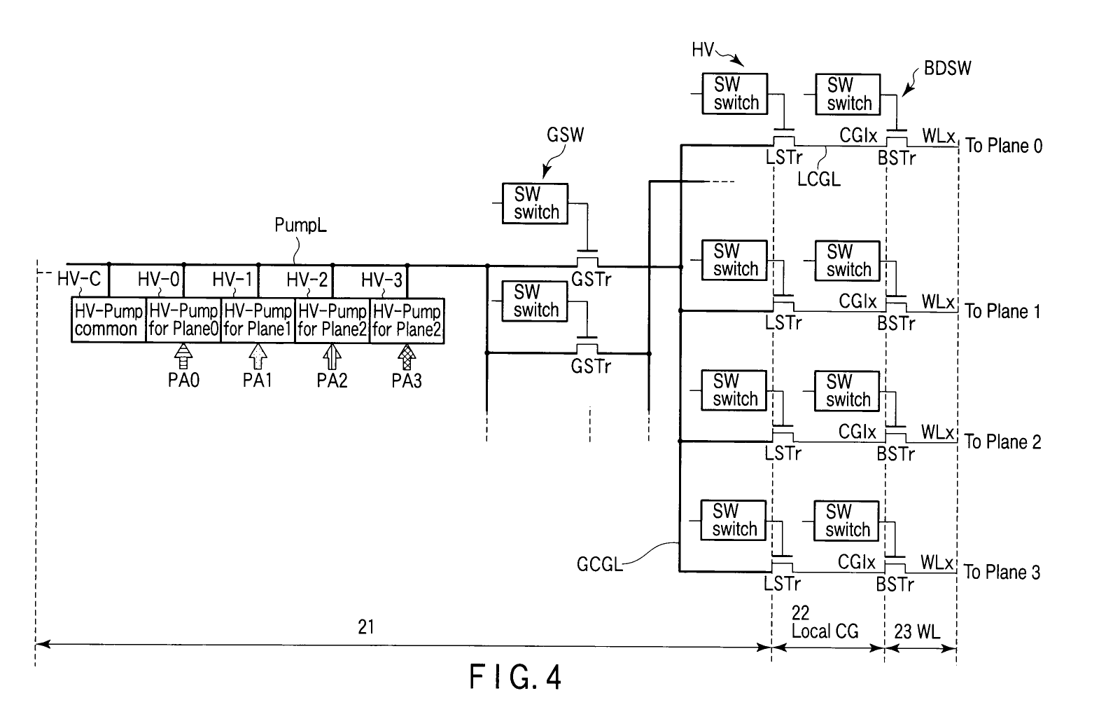

Next, referring to FIG. 4, a description is given of a structure example of wiring which is charged by the power supply generating circuit 19 according to the present embodiment.

As shown in FIG. 4, the structure of wiring, which is charged by the power supply generating circuit 19 according to the present embodiment, is a common wiring section 21, a local wiring section 22 and a word line section 23.

The common wiring section 21, as indicated by a heavy line in FIG. 4, comprises the pump section wiring PumpL and global control gate line GCGL. The pump section wiring PumpL electrically connects the common voltage generating circuit HV-C and voltage generating circuits HV-0 to HV-3, on the one hand, and the global switch circuit GSW, on the other hand. The global switch circuit GSW comprises a plurality of switching circuits SW and a plurality of switching transistors GSTr. One end of the current path of the switching transistor GSTr is connected to the pump section wiring PumpL and the other end of the current path is connected to the global control gate line GCGL, and the ON/OFF of the current path is switched by an output signal from the switching circuit SW, which is input to the gate of the switching transistor GSTr. The global control gate line GCGL electrically connects the global switch circuit GSW and the local switch circuit HV.

The local wiring section 22, as indicated by a thin line in FIG. 4, electrically connects the local switch circuit HV and a block decoder switch circuit BDSW. In addition, the local switch circuit HV comprises a plurality of switching circuits SW and a plurality of switching transistors LSTr. One end of the current path of the switching transistor LSTr is connected to the global control gate line GCGL and the other end of the current path is connected to the block decoder switch circuit BDSW, and the ON/OFF of the current path is switched by an output signal from the switching circuit SW, which is input to the gate of the switching transistor LSTr.

The word line section 23, as indicated by a thin line in FIG. 4, electrically connects the block decoder switch circuit BDSW and the planes (Plane0 to Plane3). The block decoder switch circuit BDSW is disposed in the block decoder (BD0 to BD3), and comprises a plurality of switching circuits SW and a plurality of switching transistors BSTr. One end of the current path of the switching transistor BSTr is connected to the local control gate line LCGL and the other end of the current path is connected to the word line WLx, and the ON/OFF of the current path is switched by an output signal from the switching circuit SW, which is input to the gate of the switching transistor BSTr.

### 1-5. Total of Wiring Load Capacitance

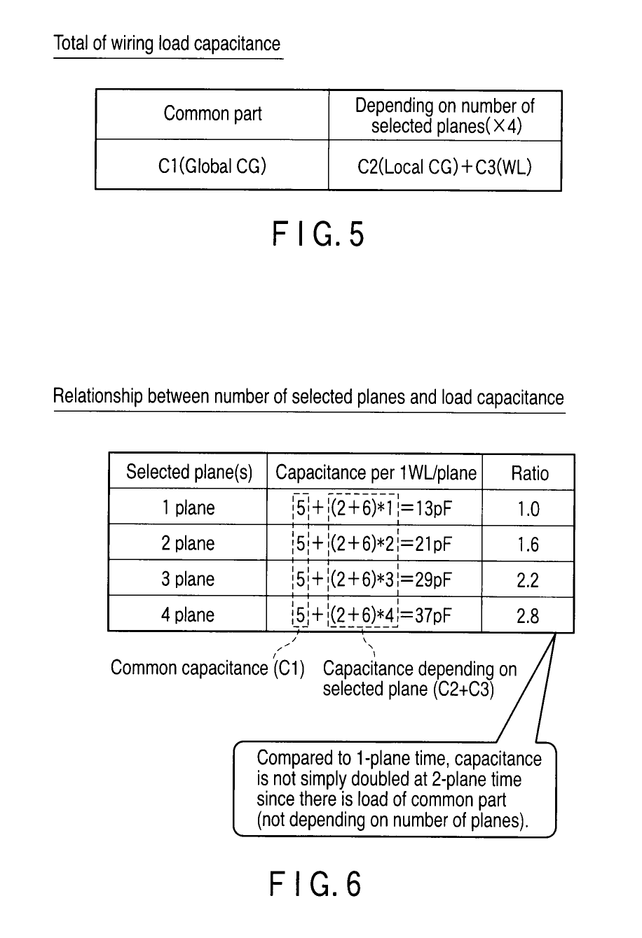

Next, referring to FIG. 5, a description is given of the total of the wiring load capacitances which are charged by the power supply voltage generating circuit 19 according to the present embodiment. As has been described above, the NAND flash memory according to this embodiment includes the memory cell array 11 which is divided into the four planes (PL0 to PL3).

As shown in FIG. 5, the total of the wiring load capacitances, which are charged by the power supply voltage generating circuit 19, is the total of a load capacitance C1 of the common section and a load capacitance, (C2+C3)×4, of the part depending on the number of select planes. Specifically, there is the following correspondency in the wiring structure in

### FIG. 4:

Common part C1: the load capacitance of common wiring part 21 (“heavy line” in FIG. 4), and

Part (C2+C3) depending on the number of select planes: the load capacitance of the local wiring section 22 and word line section 23 (“thin line” in FIG. 4).

It is thus understood that the wiring load capacitance, which is charged by the power supply voltage generating circuit 19, comprises the load capacitance C1 which commonly appears if the global switch circuit GSW is turned on, without depending on the number of selected planes, and the part (C2+C3) depending on the number of selected planes corresponding to the plural planes (PL0 to PL3).

### 1-6. Relationship Between the Number of Selected Planes and the Load Capacitance

Next, referring to FIG. 6, a description is given of the relationship between the number of selected planes and the load capacitance in the present embodiment.

As shown in the middle part of FIG. 6 (capacitance per 1WL/Plane), in the semiconductor integrated circuit device having plural planes of two or more planes, the load capacitance, which is to be charged, varies when one plane is selected and when two or more plural planes are selected at the same time. In this example, in consideration of the wiring length and the number of transistors, the capacitance of each wiring was provisionally calculated on the assumption that the capacitance of the word line is about 2 pF, the capacitance of the local control gate line is about 6 pF, and the capacitance of the global control gate line GCGL is about 5 pF.

As a result, in the 4-plane configuration in the present embodiment, the capacitance varies in the following manner.

Case of 1 Plane selection: 5+(2+6)×1=about 13 pF

Case of 2 Plane selection: 5+(2+6)×2=about 21 pF

Case of 3 Plane selection: 5+(2+6)×3=about 29 pF

Case of 4 Plane selection: 5+(2+6)×4=about 37 pF.

As described above, if the load capacitance varies depending on the number of selected planes, the charging time greatly varies accordingly, leading to degradation in operation margin. Thus, there is an idea that the capability of the power supply voltage generating circuit should be varied depending on the number of selected planes.

However, it is not easy to execute such control as to exactly vary the supply capability of the power supply voltage generating circuit in accordance with the load capacitance which varies depending on the number of selected planes.

The reason for this is that, as indicated in the provisional calculation in the present example as shown in FIG. 6, in the case of the semiconductor integrated circuit device of the 4-plane configuration, the load capacitances in the 1-plane operation, 2-plane operation time and 4-plane operation do not simply increase in such a manner that the load capacitance increases two times or four times, compared to the load capacitance at the time of the 1-plane operation.

As shown in FIG. 6, it is clear that the load capacitance in the 2-plane operation is not double the load capacitance in the 1-plane operation. In the provisional calculation, even if the number of selected planes increases two times and four times, the load capacitance increases about 1.6 times and about 2.8 times.

The reason for this is that the load capacitance C1 of the common part is present, regardless of the number of selected planes. In the present example, the load capacitance C1 of the common part corresponds to the capacitance of about 5 pF of the global control wiring.

As a countermeasure, it may be thought to adopt such a structure that a voltage generator is provided for each of the planes, and the voltage generator is operated only when the associated plane is selected. However, in this structure, at the times of the 2-plane operation and 4-plane operation, the capabilities of the associated voltage generators become two times greater and four times greater, which do not correspond to the actual variations in load capacitance. Furthermore, compared to the actual variations in load capacitance, excessive capabilities are provided when plural planes are selected. Besides, in this structure, a decrease in operation margin is caused by the non-uniformity in word line rising speed due to the number of selected planes, and voltage generators having excessive capabilities, compared to the load, are needed, resulting in a possible increase in layout area and a possible increase in power consumption.

Taking the above into account, the present embodiment proposes the power supply voltage generating circuit 19 including the common voltage generating circuit HV-C having a fixed supply capability without depending on the number of plural planes (PL0 to PL3), and the plural voltage generating circuits (HV-0 to HV-3) which are disposed in accordance with the number of planes (PL0 to PL3).

The common voltage generating circuit HV-C charges the load capacitance C1 of the common part, which does not depend on the number of plural planes (PL0 to PL3). On the other hand, the plural voltage generating circuits (HV-0 to HV-3) charge the load capacitance (C2+C3) of the part depending on the number of selected planes.

For example, at the time of a data read operation and at the time of a data write operation, when one plane is selected (in this example, plane PL0 is selected), the local switch circuit HV of the plane PL0 and the block decoder (word line) switch circuit BDSW, in addition to the global switch circuit GSW of the common part, are turned on.

In this case, the capacitance, which is to be charged by the power supply voltage generating circuit 19, is the total of the load capacitance C1 of the common part and the load capacitance (C2+C3) of the part corresponding to the number of selected planes (PL0). In other words, this capacitance is the capacitance of the global CG line+the capacitance corresponding to the plane PL0 (local CG line capacitance+word line capacitance). In this case, the power supply voltage generating circuit, which operates, is the common voltage generating circuit HV-C and one voltage generating circuit HV-0 that is the pump circuit for the plane PL0.

Next, for example, at the time of a data read operation and at the time of a data write operation, when the four planes are selected (planes PL0 to PL3 are selected), the capacitance, which is to be charged by the power supply voltage generating circuit 19, is the total of the load capacitance C1 of the common part and four times the load capacitance (C2+C3) of the part corresponding to the number of selected planes (PL0). In other words, this capacitance is the capacitance of the global CG line+(local CG line capacitance+word line capacitance)×4. In this case, the power supply voltage generating circuit, which operates, is the common voltage generating circuit HV-C and four voltage generating circuits HV-0 to HV-3 for the planes PL0 to PL3.

As has been described above, with the provision of the common voltage generating circuit HV-C, even if there is a load variation due to the change of the number of selected planes, optimal control can easily be executed at all times. Thus, even in the case where the multi-plane configuration of two or more planes is promoted and the capacitance load varies due to the change of the number of selected planes, it is possible to prevent the time for charging from varying due to the number of selected planes. Therefore, the operation margin can be improved.

Moreover, it is possible to make use of the four voltage generating circuits HV-0 to HV-3 for planes, which have the same voltage supply capability and the same structure. Thus, the time period for development can advantageously be reduced in that the control therefor is very easy and the work load for layout can greatly be reduced.

### <2. Rising Voltage Characteristics>

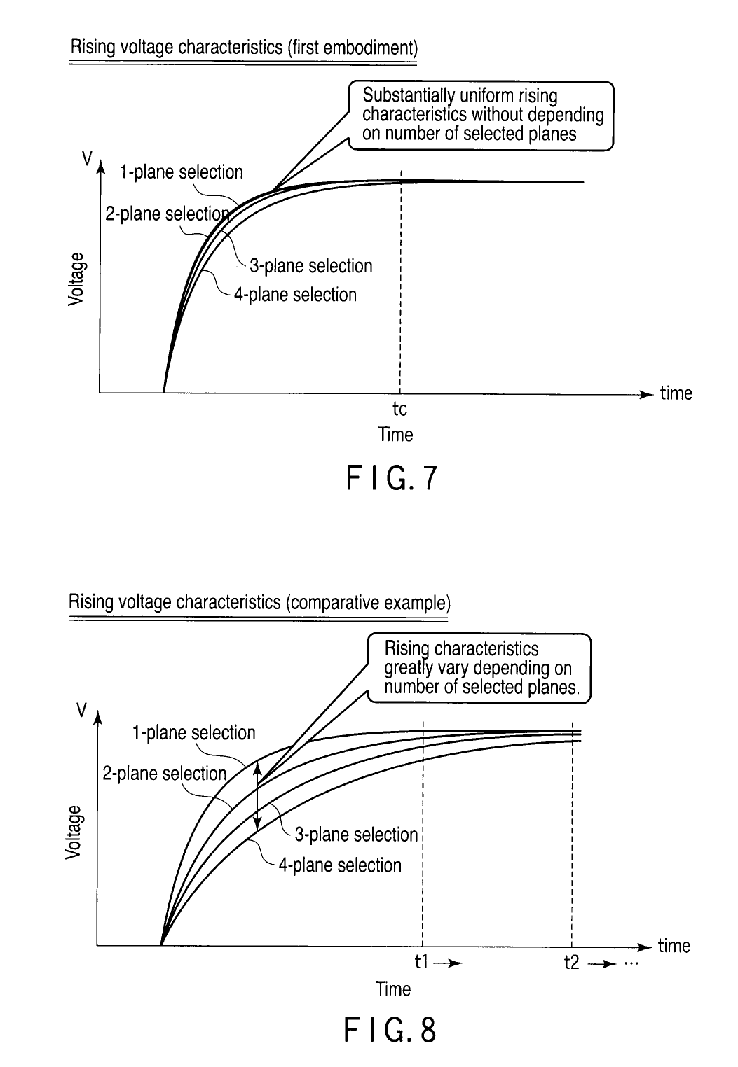

Next, referring to FIG. 7 and FIG. 8, a description is given of the rising voltage characteristics of the semiconductor integrated circuit device.

### 2-1. Rising Speed in the First Embodiment

To begin with, referring to FIG. 7, a description is given of the rising voltage characteristics of the semiconductor integrated circuit device according to the first embodiment.

As shown in FIG. 7, as regards the relationship between time (time) and a voltage (V), substantially uniform rising characteristics are realized in each of the cases of 1-plane section, 2-plane section, 3-plane section and 4-plane selection. For example, in the present embodiment, regardless of the selection of one to four planes, the load capacitance can be charged at a substantially fixed time tc.

It is thus understood that according to the structure of the present embodiment, substantially uniform rising characteristics can be obtained, without depending on the number of selected planes.

### 2-2. Rising Speed in Comparative Example

Next, referring to FIG. 8, a description is given of the rising voltage characteristics of a semiconductor integrated circuit device according to a comparative example which will be described later.

As shown in FIG. 8, as regards the relationship between time (time) and a voltage (V), rising characteristics greatly vary between the cases of 1-plane section, 2-plane section, 3-plane section and 4-plane selection. In the case of the comparative example, the charging time of the load capacitance gradually increases (time t1→time t2, . . . ) as the number of selected planes becomes larger in the order of one plane, two planes, three planes and four planes.

It is thus understood that according to the structure of the comparative example, the rising characteristics greatly vary depending on the number of selected planes.

### <3. Advantageous Effects>

According to the semiconductor integrated circuit device of the first embodiment, at least the following advantageous effects (1) to (3) can be obtained.

(1) The operation margin can be improved.

As has been described above, the semiconductor integrated circuit device according to the first embodiment comprises a memory cell array 11 including a plurality of planes PL0 to PL3 each including a plurality of memory cells MT; a power supply voltage generating circuit 19 including a common voltage generating circuit HV-C which maintains a fixed supply capability, and a plurality of voltage generating circuit HV-0 to HV-3 which are disposed in accordance with the number of the plurality of planes; and a control circuit 17 configured to control the power supply voltage generating circuit 19.

The common voltage generating circuit HV-C charges the load capacitance C1 of the common part, which does not depend on the number of plural planes (PL0 to PL3). On the other hand, the plural voltage generating circuits (HV-0 to HV-3) charge the load capacitance (C2+C3) of the part depending on the number of selected planes.

For example, at the time of a data read operation and at the time of a data write operation, when one plane is selected (in this example, plane PL0 is selected), the capacitance, which is to be charged by the power supply voltage generating circuit 19, is the total of the load capacitance C1 of the common part and the load capacitance (C2+C3) of the part corresponding to the number of selected planes (PL0). In other words, this capacitance is the capacitance of the global CG line+the capacitance corresponding to the plane PL0 (local CG line capacitance+word line capacitance). In this case, the power supply voltage generating circuit, which operates, is the common voltage generating circuit HV-C and one voltage generating circuit HV-0 that is the pump circuit for the plane PL0.

Next, for example, at the time of a data read operation and at the time of a data write operation, when the four planes are selected (planes PL0 to PL3 are selected), the load capacitance, which is to be charged by the power supply voltage generating circuit 19, is the total of the load capacitance C1 of the common part and four times the load capacitance (C2+C3) of the part corresponding to the number of selected planes (PL0). In other words, this capacitance is the capacitance of the global CG line+(local CG line capacitance+word line capacitance)×4. In this case, the power supply voltage generating circuit, which operates, is the common voltage generating circuit HV-C and four voltage generating circuits HV-0 to HV-3 for the planes PL0 to PL3.

As has been described above, even if there is a load variation due to the change of the number of selected planes with the promotion of the multi-plane configuration, optimal control can easily be executed at all times. Thus, even in the case where the capacitance load varies due to the change of the number of selected planes, it is possible to prevent the charging time from varying due to the number of selected planes. Therefore, the operation margin can be improved.

This is clear from the rising voltage characteristics of the semiconductor integrated circuit device, as shown in FIG. 7, which are based on the knowledge acquired by the inventor of the present invention.

(2) The time period for development can advantageously be reduced.

Moreover, it is possible to make use of the four voltage generating circuits HV-0 to HV-3 for planes, which have the same voltage supply capability and the same structure. Thus, the time period for development can advantageously be reduced in that the control therefor is very easy and the work load for layout can greatly be reduced.

(3) The capacity can advantageously be increased.

In order to realize the increase in capacity, it is thought to be a prospective solution to construct a memory cell array in a multi-plane configuration, while promoting microfabrication of memory cells.

In the present embodiment, as described above in connection with the advantageous effect (1), the multi-plane configuration can be adopted without degrading the operation margin. Thus, the capacity can advantageously be increased. In addition, it is expected that the structure of the present embodiment is prospective, for example, for the 30 nm generation and 20 nm generation, in which memory cells are further shrunk.

### Second Embodiment

### Example in which Well Voltage is Controlled in Accordance with the Number of Selected Planes

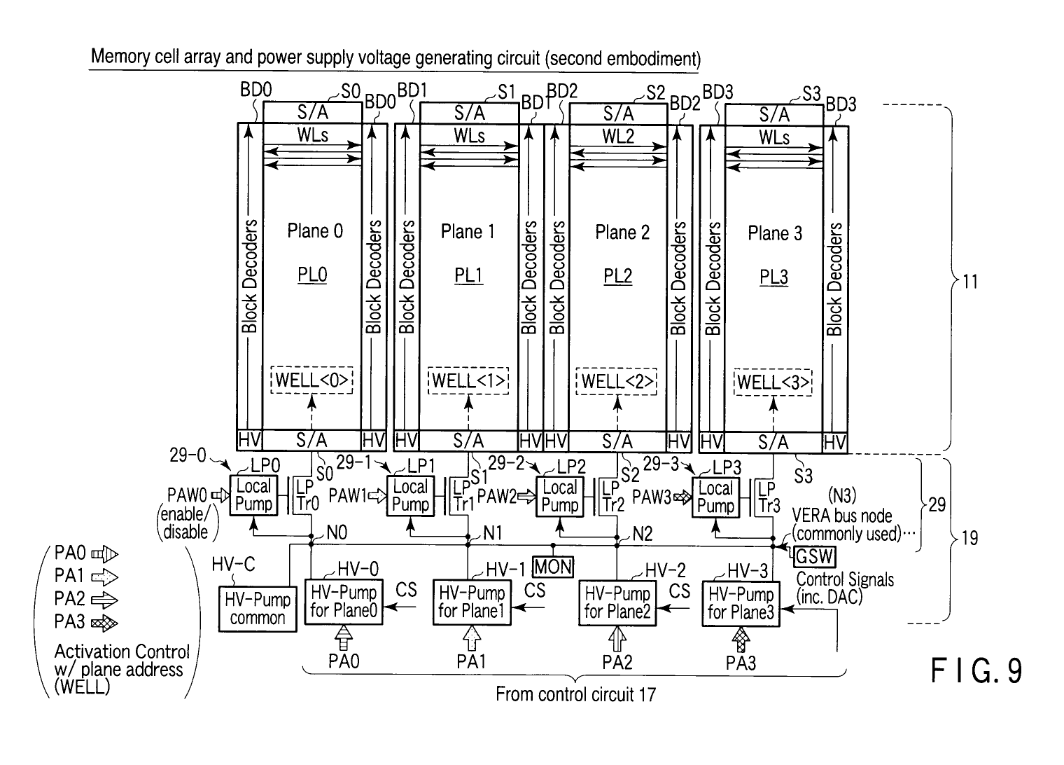

Next, a semiconductor integrated circuit device according to a second embodiment of the invention is described with reference to FIG. 9. This embodiment relates to an example in which a well voltage is further controlled in accordance with the number of selected planes. In the description below, a detailed description of the parts common to those of the first embodiment is omitted.

### <Structure Example>

As shown in FIG. 9, the semiconductor integrated circuit device according to the second embodiment differs from the first embodiment in the following respects.

As regards the memory cell array 11, block decoders BD and local switch circuits HV are additionally disposed at both ends of the planes PL0 to PL3. Thus, even if the microfabrication of memory cells is advanced, the margin of lithography of the block decoders BD0 to BD3 can advantageously be increased. To be more specific, in the case where one plane comprises, for example, about 2000 blocks, it is necessary to dispose 2000 block decoders BD0 to BD3, the number of which is the same as the number of blocks. If block decoders are disposed only on one side of the plane, it is necessary to dispose 2000 block decoders on one side with the same pitch as the blocks. On the other hand, as in the present embodiment, in the structure in which the block decoders BD0 to BD3 are disposed on both sides of the planes PL0 to PL3, it should suffice if 1000 block decoders are disposed on each of both sides of the plane. Accordingly, since the block decoders BD0 to BD3 can be disposed with the double the pitch of blocks, the margin of the lithography can be improved.

The power supply voltage generating circuit 19 further includes erase change-over switch circuits 29-0 to 29-3 and an erase voltage monitor circuit MON, thereby to independently control the well voltages for the respective planes, and to make constant the rising of an erase voltage at the time of an erase operation.

At the time of the erase operation, the erase voltage monitor circuit MON switches the outputs of common nodes N0 to N3 to the plural erase change-over switch circuits 29-0 to 29-3 in accordance with a control signal from the control circuit 17.

The erase change-over switches 29-0 to 29-3 have current paths connected at one end to the common nodes N0 to N3, which are connected to the output of the common voltage generating circuit HV-C and the outputs of the plural voltage generating circuits HV-0 to HV-3, and at the other end to wells WELL<0> to WELL<3> to which erase voltages of plural planes are applied.

The erase change-over switches 29-0 to 29-3 comprise local pump circuits (LP0 to LP3) and switching transistors (LPTr0 to LPTr3).

The local pump circuit LP0 controls the conduction/non-conduction of the current path of the switching transistor LPTr0 in accordance with a well control signal PAWO (enable/disable) from the control circuit 17. The same substantially applies to the other local pump circuits LP1 to LP3.

One end of the current path of the switching transistor LPTr0 is connected to an erase voltage bus node (VERA bus node) N0, and the other end of the current path is connected to the well WELL<0> in the semiconductor substrate, to which an erase voltage VERA is applied at the time of the erase operation of the plane PL0. The gate of the switching transistor LPTr0 is connected to the local pump circuit LP0. The same substantially applies to the other switching transistors LPTrl to LPTr3.

The erase voltage bus nodes (VERA bus node) N0 to N3 are commonly used with the nodes N0 to N3 in FIG. 3 in the first embodiment. Thus, such a configuration may be adopted that electrical connection is established to the global switch circuit GSW of the first embodiment via the nodes N0 to N3.

The switching at the time of applying the well voltage in this embodiment is executed by the erase voltage monitor circuit MON in accordance with the control by the control circuit 17.

### <Data Erase Operation (Well Voltage Application Operation)>

Next, a description is given of a data erase operation (well voltage application operation) of the semiconductor integrated circuit device according to the second embodiment.

In the NAND flash memory, when data of the memory cell MT is erased, a high erase voltage (VERA) is applied to the well side of the semiconductor substrate in which the memory cell MT is formed, and electrons are extracted from the charge accumulation layer FG. In the case of the multi-plane configuration as in this embodiment, since the load capacity of the well is very large, it is desirable to apply a high voltage to only the well of the plane in which a to-be-erased block is present.

However, also in the case of independently controlling the erase voltage for the respective planes, if the rising of the erase voltage greatly varies between the erase at the time of 1-plane selection, the erase at the time of 2-plane selection and the erase at the time of 4-plane section, a large variance occurs in effective voltage application time depending on the number of selected planes, leading to a large difference in erase characteristics. Thus, it is desirable to uniformly control the charge speed, regardless of the number of selected planes. Besides, if the same power supply voltage generating circuit as with the 4-plane selection is used at the time of 1-plane selection, the capability is excessive and a large current consumption occurs undesirably.

To address this problem, in the second embodiment, the above-described power supply voltage generating circuit 19, which comprise the common power supply voltage circuit HV-C and the plural voltage generating circuits HV-0 to HV-3 for planes, the number of which is the same as the number of planes, is also used in the data erase operation.

To be more specific, if erase control signals (Control Signals (inc.DAC)) are commonly input from the control circuit 17 to the power supply voltage generating circuits HV-0 to HV-3, the erase voltage monitor circuit MON switches the current paths of the erase voltage bus nodes N0 to N3 to the well side, thereby transitioning to the data erase operation.

Subsequently, like the first embodiment, control signals PA0 to PA3, and PAWO to PAW3 are input from the control circuit 17 to the voltage generating circuits HV-0 to HV-3 and local pump circuits LP0 to LP3. Thereby, as in the first embodiment, well voltages are applied to the wells (WELL<0> to WELL<3>) of the selected planes.

Therefore, at the time of the data erase operation, even if the number of selected planes varies, a substantially uniform charging speed can be maintained at all times.

### ADVANTAGEOUS EFFECTS

According to the semiconductor integrated circuit device of the second embodiment, at least the same advantageous effects (1) to (3) as described above can be obtained. Furthermore, the following advantageous effect (4) can be obtained.

(4) The operation margin can be improved also in the data erase operation

In the semiconductor integrated circuit device according to the second embodiment, the power supply voltage generating circuit 19 further includes the local pump circuits (LP0 to LP3), switching transistors (LPTr0 to LPTr3) and erase voltage monitor circuit MON.

Thus, if erase control signals (Control Signals (inc.DAC)) are commonly input from the control circuit 17 to the power supply voltage generating circuits HV-0 to HV-3, the erase voltage monitor circuit MON switches the current paths of the erase voltage bus nodes N0 to N3 to the well side, thereby transitioning to the data erase operation.

Subsequently, like the first embodiment, control signals PA0 to PA3, and PAWO to PAW3 are input from the control circuit 17 to the voltage generating circuits HV-0 to HV-3 and local pump circuits LP0 to LP3. Thereby, as in the first embodiment, well voltages are applied to the wells (WELL<0> to WELL<3>) of the selected planes.

Therefore, at the time of the data erase operation, even if the number of selected planes varies, a substantially uniform charging speed can be maintained at all times. As a result, the operation margin can be improved also in the data erase operation.

### Third Embodiment

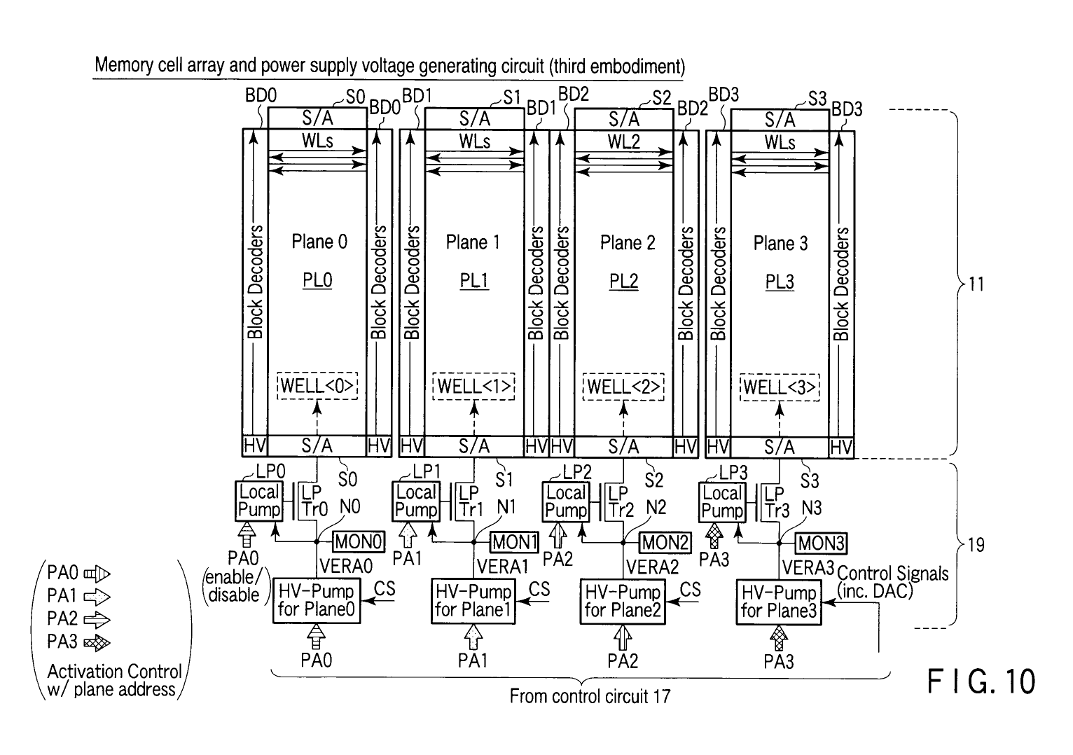

Next, a semiconductor integrated circuit device according to a third embodiment of the invention is described with reference to FIG. 10. In the description below, a detailed description of the parts common to those of the second embodiment is omitted.

As shown in FIG. 10, the semiconductor integrated circuit device of the third embodiment differs from that of the second embodiment in that the semiconductor integrated circuit device of the third embodiment further includes erase voltage monitor circuits MON0 to MON3 which have outputs connected to the erase voltage bus nodes N0 to N3. The erase voltage monitor circuits MON0 to MON3 switch the erase voltage bus nodes N0 to N3 in accordance with the control by the control circuit 17, so as to apply desired well voltages to the planes PL0 to PL3.

According to the semiconductor integrated circuit device of the third embodiment, at least the same advantageous effects (1) to (4) as described above can be obtained. The structure of the third embodiment is applicable, where necessary.

### Comparative Example

### Example of Batchwise Control of Planes

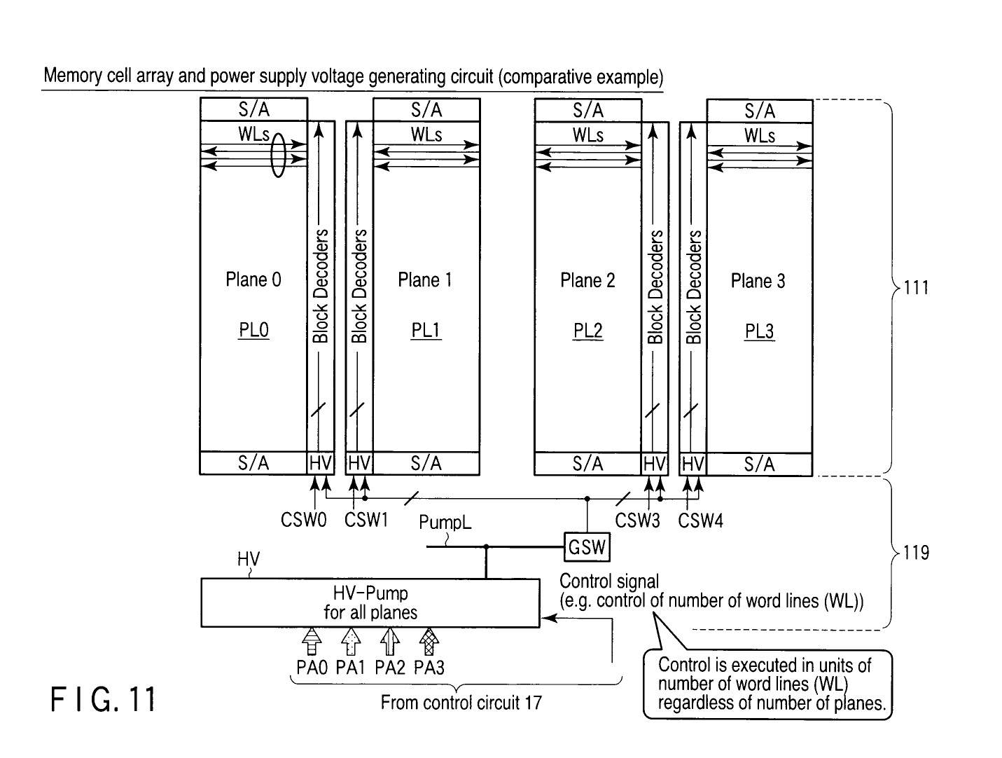

Next, referring to FIG. 11, a description is given of a semiconductor integrated circuit device according to a comparative example, for the purpose of comparison with the semiconductor integrated circuit devices according to the first to third embodiments. This comparative example relates to an example of batch-control of power supply voltages of planes. In the description below, a detailed description of the parts common to those of the first embodiment is omitted. The structure of the present comparative example does not show an objective prior-art structure at the time of filing of the present application, but is an example for comparison with the semiconductor integrated circuit devices according to the first to third embodiments.

As shown in FIG. 11, the comparative example is common to the first to third embodiments in that a memory cell array 111 of the comparative example includes a plurality of planes (PL0 to PL3).

On the other hand, the comparative example differs from the first to third embodiments in that a power supply voltage generating circuit 119 includes only a single voltage generating circuit HV (HV-Pump for all planes), and a power supply voltage is applied by only the voltage generating circuit HV regardless of the number of selected planes.

Thus, in the structure of the comparative example, for example, at the time of a data read operation and at the time of a data write operation, power supply voltages that are supplied are controlled by control signals which are input in association with the number of word lines (e.g. 4, 8, 16, . . . ), irrespective of the number of selected planes. In the case of a single-plane configuration, even with this structure and control, no degradation occurs in the operation margin due to the variation of the load capacitance.

However, in the semiconductor integrated circuit device having a plurality of planes of two or more planes, the load capacitance, which is to be charged, varies between when one plane is selected and when a plurality of planes of two or more planes are selected at the same time. The charging time greatly varies depending on the number of selected planes, leading to degradation in operation margin. Thus, there is an idea that the capability of the power supply voltage generating circuit should be varied depending on the number of selected planes, but it is not easy to execute such control as to exactly vary the supply capability of the power supply voltage generating circuit in accordance with the load capacitance which varies depending on the number of selected planes.

As indicated by the provisional calculation in FIG. 6, in the case of the semiconductor integrated circuit device of the 4-plane configuration, the load capacitances in the 1-plane operation, 2-plane operation time and 4-plane operation do not simply increase in such a manner that the load capacitance increases two times or four times, compared to the load capacitance at the time of the 1-plane operation.

Consequently, in the structure of the comparative example, as shown in FIG. 8, the rising voltage characteristics vary such that the charging time of the load capacitance gradually increases (time t1→time t2, . . . ) as the number of selected planes becomes larger in the order of one plane, two planes, three planes and four planes.

In the structure and operation of the comparative example, if the multi-plane configuration of two or more planes is promoted, the load capacitance varies in accordance with the variation of the number of selected planes, and consequently the charging time greatly varies depending on the number of selected planes. Thus, the operation margin decreases disadvantageously. Moreover, the structure and operation of the comparative example are disadvantageous for an increase in capacity.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit comprising:
a memory cell array including a plurality of planes each including a plurality of memory cells;
a power supply voltage generating circuit including a common voltage generating circuit which maintains a fixed voltage supply capability, and a plurality of voltage generating circuits which are disposed in accordance with a number of the plurality of planes; and
a control circuit configured to control the power supply voltage generating circuit.

2. The circuit of claim 1, further comprising a global switch circuit configured to switch and supply a power supply voltage, which is supplied from the common voltage generating circuit and the plurality of voltage generating circuits, to a selected one of the plurality of planes.

3. The circuit of claim 2, wherein the global switch circuit comprises:
a switching circuit; and
a switching transistor having a current path which is ON/OFF switched by an output signal from the switching circuit which is input to a gate of the switching transistor.

4. The circuit of claim 1, wherein the common voltage generating circuit is set in an inactive state when the semiconductor integrated circuit is in a standby state.

5. The circuit of claim 1, wherein the power supply voltage generating circuit further comprises:
a plurality of change-over switch circuits having current paths connected at one end to common nodes, which are connected to an output of the common voltage generating circuit and outputs of the plurality of voltage generating circuits, and at the other end to wells to which erase voltages of the plurality of planes are applied; and
a voltage monitor circuit configured to switch outputs of the common nodes to the plurality of change-over switch circuits in accordance with control of the control circuit.

6. The circuit of claim 1, wherein the power supply voltage generating circuit further comprises:
a plurality of change-over switches having current paths connected at one end to wells to which erase voltages of the plurality of planes are applied; and
a plurality of voltage monitor circuits having outputs connected to the other ends of the plurality of change-over switch circuits, to an output of the common voltage generating circuit and to outputs of the plurality of voltage generating circuits, the plurality of voltage monitoring circuits being configured to switch the outputs to the plurality of change-over switch circuits in accordance with control of the control circuit.

7. The circuit of claim 1, wherein the plane comprises:
a plurality of blocks each comprising the plurality of memory cells disposed at intersections between a plurality of word lines and a plurality of bit lines;
a block decoder configured to select any one of the plurality of blocks in accordance with a block select signal from the control circuit; and
a local switch circuit configured to switch ON/OFF of the block decoder in accordance with a local control signal which is input from the control circuit.

8. The circuit of claim 1, wherein the common voltage generating circuit is configured to charge a load capacity of a common wiring.

9. The circuit of claim 8, further comprising a global switch circuit configured to switch and supply a power supply voltage, which is supplied from the common voltage generating circuit and the plurality of voltage generating circuits, to a selected one of the plurality of planes,
wherein the common wiring includes a pump section wiring which electrically connect the common voltage generating circuit and the plurality of voltage generating circuits, on one hand, and the global switch circuit, on the other hand.

10. The circuit of claim 8, wherein the plane comprises:
a plurality of blocks each comprising the plurality of memory cells disposed at intersections between a plurality of word lines and a plurality of bit lines;
a block decoder configured to select any one of the plurality of blocks in accordance with a block select signal from the control circuit; and
a local switch circuit configured to switch ON/OFF of the block decoder in accordance with a local control signal which is input from the control circuit,
wherein the common wiring includes a global control gate line which electrically connects the global switch circuit and the local switch circuit.

11. The circuit of claim 1, wherein the plurality of voltage generating circuits are configured to charge a load capacitance of a local wiring and word lines.

12. The circuit of claim 11, wherein the plane comprises:
a plurality of blocks each comprising the plurality of memory cells disposed at intersections between a plurality of word lines and a plurality of bit lines;
a block decoder configured to select any one of the plurality of blocks in accordance with a block select signal from the control circuit; and
a local switch circuit configured to switch ON/OFF of the block decoder in accordance with a local control signal which is input from the control circuit,
wherein the local wiring includes a wiring which electrically connects the local switch circuit and the word line.

13. The circuit of claim 1, wherein the memory cell has a multilayer structure comprising a gate insulation film, a charge accumulation layer, an inter-gate insulation film and a control electrode layer, which are successively stacked on a semiconductor substrate.

14. The circuit of claim 12, wherein the block comprises a plurality of memory cell units,
each of the plurality of memory cell units comprises a NAND string and a select transistor connected to one end or the other end of the NAND string, the NAND string comprising a plurality of memory cell transistors having current paths connected in series, and two dummy cell transistors, and
the memory cell transistors neighboring a source line and a bit line are used as the dummy cell transistors.

15. The circuit of claim 2, wherein the global switch circuit and the plurality of planes are electrically connected by a global control gate line.

16. The circuit of claim 15, wherein the common voltage generating circuit and the voltage generating circuits, on the one hand, and the global switch circuit, on the other hand, are electrically connected by a pump section wiring via nodes.

17. The circuit of claim 16, further comprising a switching transistor, one end of a current path of the switching transistor being connected to the pump section wiring, the other end of the current path of the switching transistor being connected to the global control gate line, and ON/OFF of the current path of the switching transistor being switched by an output signal from the switching circuit, which is input to a gate of the switching transistor; and
the global control gate line which electrically connects the global switch circuit and a local switch circuit.

18. The circuit of claim 7, wherein the block decoder and the local switch circuit are disposed at both ends of the plurality of planes with a double pitch.

19. The circuit of claim 1, wherein the power supply voltage generating circuit further comprises a plurality of erase change-over switch circuits and an erase voltage monitor circuit, thereby to independently control well voltages in association with the planes and to make uniform rising voltages of erase voltages at a time of an erase operation.
